(19) United States
(12) Patent Application Publication
(10) Pub. No.: US 2004/0142578 A1
(43) Pub. Date: Jul. 22, 2004

(54) Thin film nanostructures

(76) Inventors: Ulrich Wiesner, Ithaca, NY (US); Phong Du, Ithaca, NY (US); Charles T. Black, New York, NY (US); Kathryn W. Guarini, Yorktown Heights, NY (US)

Correspondence Address: William A. Blake, Jones, Tullar & Cooper, P.C., P.O. Box 2266 Eads Station, Arlington, VA, 22202, US

(21) Appl. No.: 10/400,075

(22) Filed: Mar. 27, 2003

Related U.S. Application Data
(60) Provisional application No. 60/367,770, filed on Mar. 28, 2002.

(51) Int. Cl. H01L 21/31; H01L 21/469

(52) U.S. Cl. 438/778; 438/781; 438/782

(57) ABSTRACT

The co-self-assembly of organic, e.g., block copolymer, and inorganic, e.g., sol-gel, components is employed to create nanometer features of silicon dioxide type materials in thin films on silicon surfaces. In the preferred embodiment, sol-gel chemistry is used to introduce inorganic components (preferably 3-glycidoxy-propyltrimethoxysilane and aluminum-tri-sec-butoxide) into a block copolymer (preferably poly (isoprene-block-ethylene oxide) (PI-b-PEO)), as a structure-directing agent. The inorganic components preferentially migrate to the PEO block and swell the copolymer into different morphologies depending on the amount of sol-gel precursors added. Thin films (e.g., below 100 nm) are created by spin coating the hybrid solution onto a silicon wafer. An inverse hexagonal morphology, for example, is produced in which the polymer forms nanopores within an inorganic matrix. Through heat treatment the organic phase can subsequently be removed leaving an all-inorganic porous nanostructure on the wafer.

### CROSS REFERENCE TO RELATED APPLICATIONS

This application claims the benefit, under 35 U.S.C. § 119(e), of U.S. Provisional Application No. 60/123456, which was filed on Mar. 28, 2002 and is hereby incorporated by reference.

### BACKGROUND OF THE INVENTION

1. Field of the Invention

The present invention relates in general to a method for fabricating nanostructures, i.e., structures having nanometer scale features, on silicon wafers or substrates. The area of technical interest comprises polymer directed avenues for self-assembly of silica (SiO₂)-type nanostructures in thin (e.g., tens of nm) films on silicon with potential applications as lithographic templates, scaffolds for assemblies of electronic materials or low dielectric constant materials. The techniques used to generate the SiO₂ nanostructures are chosen to be compatible with current semiconductor processing technology, which make them particularly interesting for process and device applications.

2. Description of the Background Art

The nanostructure and semiconductor device manufacturing industries are continually working to develop fabrication techniques and equipment that enable the formation of ever smaller devices. Semiconductor devices constructed with smaller feature and structure dimensions operate at faster speeds, consume less power and embody higher functional complexities. However, current photolithographic fabrication techniques have limitations that prevent the formation of devices much smaller than 150 nanometers. Among other reasons, this is because conventional photolithography is a multi-step process in which each step is prone to introducing an error in the resulting device. Nevertheless, as manufacturing techniques gravitate toward a more “bottom-up” approach, the ability to manipulate materials on the nanometer scale becomes critically important. Thus, advances in current technology demand accuracy and precision that are difficult to realize with present technology, such as photolithography. What is needed therefore is an alternative fabrication technique that can be employed to form smaller scale nanostructures.

One such alternative technique involves the self-assembly of organic block copolymer structures on a silicon wafer or substrate. It is well established that block copolymer self-assembly creates structures of well-defined size (5-100 nm) and morphology on the nanometer length scale. However, these all-organic approaches to nanostructuring of surfaces have considerable disadvantages in real-world applications. For example, all-organic techniques are incompatible with extreme fabrication techniques, such as those involving the use of high temperatures. In addition, an all-organic system has a fixed block fraction that is established at the time of polymerization and this determines the morphology of the resultant structures. Any desire to work with a different morphology would require the costly synthesis of a brand new polymer and time-consuming efforts for repeated process optimization.

In view of the foregoing, a need therefore remains for an alternative nanostructure fabrication technique that is compatible with extreme fabrication techniques and can be easily adapted for use with differing morphologies

### SUMMARY OF THE INVENTION

The present invention fulfills the foregoing need through provision of a novel technique involving the co-self-assembly of organic, e.g., block copolymer, and inorganic, e.g., sol-gel, components to create nanometer features of silicon dioxide type materials in thin films on silicon surfaces. This approach holds tremendous scientific and technological promise potentially enabling technologies in a broad variety of fields ranging from microelectronics to biomolecular detection.

The present invention overcomes the aforementioned drawbacks of all-organic techniques through the generation of organic-inorganic hybrid systems, preferably of the silica type. In the preferred embodiment, sol-gel chemistry is used to introduce inorganic components (preferably 3-glycidoxy-propyltrimethoxysilane and aluminum-tri-sec-butoxide) into a block copolymer (preferably poly (isoprene-block-ethylene oxide) (PI-b-PEO)), as a structure-directing agent. The inorganic components preferentially migrate to the PEO block and swell the copolymer into different morphologies depending on the amount of sol-gel precursors added. In this way, one block copolymer can be used to obtain a whole range of bulk hybrid morphologies.

In the present invention, this approach is applied to thin films (e.g., below 100 nm). The films are created by spin coating a hybrid organic-inorganic solution onto a silicon wafer. Through co-assembly of organic and inorganic components, e.g., an inverse hexagonal morphology can be produced in which the polymer forms nanopores within an inorganic matrix. Through heat treatment, the organic phase can subsequently be removed leaving an all-inorganic porous structure. A major advantage of this approach is its full compatibility with current microelectronics fabrication processes.

### BRIEF DESCRIPTION OF THE DRAWINGS

The features and advantages of the invention will become apparent from the following detailed description of a number of preferred embodiments thereof, taken in conjunction with the accompanying drawings, in which:

FIG. 1 is a schematic illustration of a process for producing nanostructures in accordance with the preferred embodiment of the present invention;

FIGS. 2a, 2b and 2c are AFM images of nanostructures that were formed using the process of the present invention, but with different process parameters;

FIGS. 3a and 3b are AFM images of two different nanostructures that were formed using the process of the present invention, but with different copolymer molecular weights; and

FIGS. 4a and 4b are SEM images of the cross section of multilayer and monolayer nanostructures, respectively, that were formed using the process of the present invention.

### DETAILED DESCRIPTION OF THE PREFERRED EMBODIMENT

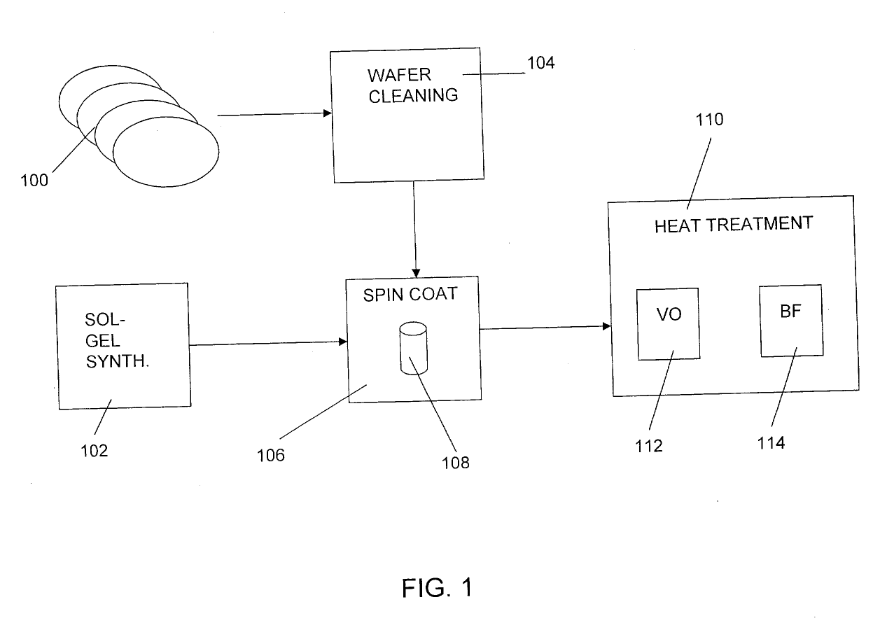

FIG. 1 is a schematic illustration of the overall steps employed to carry out the nanostructure fabrication process in accordance with the preferred embodiment of the present invention. One or more silicon wafers 100 to be coated with a nanostructure thin or thick film are provided. First, at step 102, the sol-gel solution that will form the hybrid organic-inorganic coating material is synthesized. Next, at step 104, the silicon wafers 100 to be coated are cleaned.

Once the wafers 100 have been cleaned, they are spin coated with the sol-gel solution at step 106. This step employs the use of a conventional spin chuck 108, which can rotate the wafers 100 at speeds up to 5000 RPM or more. The sol-gel solution is first dispensed onto the wafers 100 and then the spin chuck 108 is rotated to insure that the wafers 100 are evenly coated with the sol-gel solution.

Next, the coated wafers 100 are heat treated at step 110, first by being baked in a vacuum oven 112 and then being calcined in a box furnace 114. The heat treating step causes the organic silica components to condense, thereby leaving an inorganic hexagonal box nanostructure on the wafers 100.

In the preferred embodiment, the foregoing steps are carried out in the following detailed manner.

I. Sol-Gel Synthesis

The complete sol-gel synthesis can de divided up into three sections: solvation of the polymer; preparation of the sol-gel precursor; and, precursor integration with the polymer. It should be noted that slightly different parameters are employed, depending upon whether a multilayer thick film or a monolayer thin film structure is to be formed with the coating on a wafer.

A. Solvation of Polymer

The salvation step is carried out using the following sub steps. First, a selected amount of copolymer, specifically poly(isoprene-block-ethylene oxide) (PI-b-PEO), is measured out into a small vial. For multilayer thick films, 0.05 g is used, while 0.01 g is used for monolayer thin films. Next, 5 g of cholorom and 5 g of tetrahydrofuran are added to the vial. The solution is then stirred for an hour, e.g., using a small spin bar inserted in the vial.

B. Sol-Gel Precursor Preparation

5.3 g of 3-glycidoxy-propyltrimethoxysilane (GLYMO) and 1.4 g of aluminum-tri-sec butoxide (Al-bu-O) are measured into a small beaker, 0.04 g of KCl are added and the beaker is placed in an ice bath and cooled to 0° C. The solution is stirred with a spinbar and 0.27 mL of 0.01M aqueous hydrochloric acid solution is drop wise added to the beaker and stirred for 15 min. Next, the beaker is removed from the ice bath and the solution is allowed to warm up to room temperature. Finally, an additional 1.7 mL of 0.01 aqueous hydrochloric acid solution is drop wise added and the solution is stirred for 20 min.

C. Precursor-Polymer Integration

To integrate the sol-gel precursor with the block copolymer, the precursor solution is withdrawn from the beaker with a syringe and a 0.45 micron nylon filter is attached to the syringe. A selected amount (0.06 g for monolayer thin films and 0.3 g for multilayer thick films) of the sol-gel precursor solution is added to the copolymer solution in the vial and stirred for an additional 1 hour.

II. Wafer Cleaning

After the hybrid solution undergoes its final hour of stirring, the solution can be used for spin coating on the silicon wafers. However, the silicon wafers need to be cleaned before they can be subjected to the spin coating process. This is preferably accomplished by first cleaning the silicon wafers in two solution baths:

Bath 1

Deionized water, Ammonium Hydroxide(˜35%), Hydrogen Peroxide(˜35%) mixed in a 5:1:1 ratio.

Bath 2

Deionized water, Hydrochloric Acid (˜35%), Hydrogen Peroxide (˜35%) mixed in a 6:1:1 ratio.

The wafers are treated sequentially and preferably spend 20 minutes in each bath at 70 degrees Celsius. Finally, the wafers are immersed in a solution of 49% hydrofluoric acid (HF) at room temperature to remove any oxide layer.

III. Spin Coating Process

A conventional spin coating chuck can be employed to apply the hybrid solution to the silicon wafers. The following operational parameters are preferably used for the spin coating cycle:

a) Rotation speed: 5000 rotations per minute (RPM) for multilayer thick films and 2000 RPM for monolayer thin films.

b) Acceleration: 250 revolutions per second per second for multilayer thick films and 100 revolutions per second per second for monolayer thin films.

c) Total spin time: 65 seconds

The wafer is flooded with the hybrid polymer/sol-gel solution and the spin cycle is executed, thereby evenly coating the wafer with the solution.

IV. Treatment

After the spin coating, the coated wafer needs to be treated in order to fully condense the silica and produce the inverse hexagonal structure. First, the wafer is baked in a vacuum oven, preferably for one hour at 130° C. Finally, the wafer is calcined in a box furnace, preferably at a set point temperature of 500° C., a ramp rate of 5° C./minute and a soak time of 1 hour. After this final treatment in the box furnace, the sample should now posses the inverse hexagonal structure.

Experiments were conducted to verify the results obtained with the present invention. Characterization of the resulting thin film can be carried out with the use of an Atomic Force Microscope (AFM). FIGS. 2a-2c are a sequence of AFM images of different thin (˜50 nm) films that were formed using the inventive process. These images demonstrate the increasing structure control obtained through a systematic variation of processing parameters including spinner acceleration, spinning rate, solvent, or composition and concentration of sol-gel precursor and block copolymer solution. Further, these images clearly demonstrate that the structure approaches the same degree of order obtained in pure block copolymer self-assembly on surfaces.

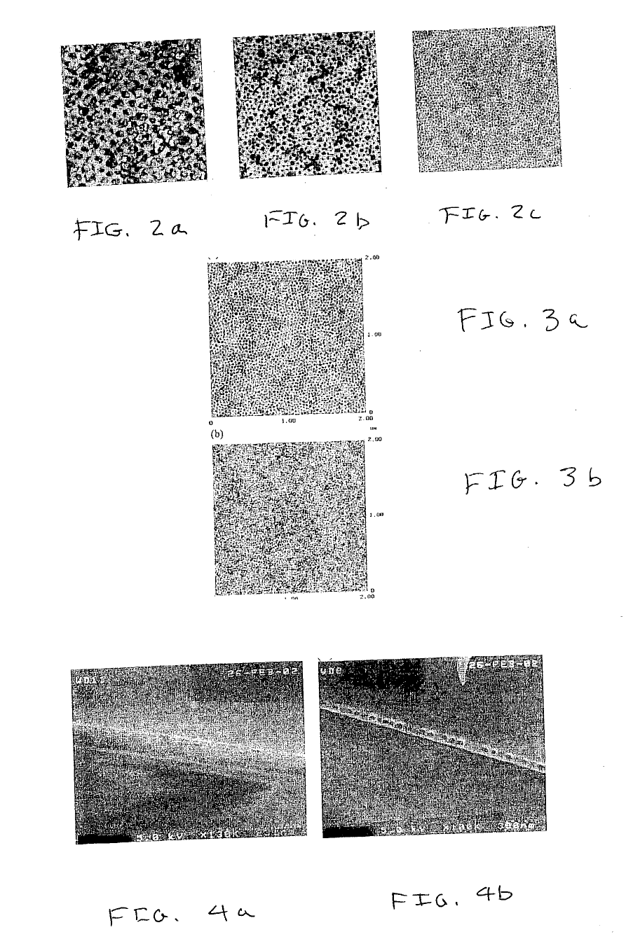

FIGS. 3a and 3b are two AFM images of thin films (˜50 nm, left side) demonstrating that the pore sizes of the silica-type nanostructures can be conveniently changed by varying the block copolymer molecular weight. In FIG. 3a, a 32,000 g/mol molecular weight PI-b-PEO polymer sample with sol-gel precursors was used and yielded a nanostructure repeat unit size of 37 nm. In FIG. 3b, the molecular weight of the PI-b-PEO polymer was reduced to 16,000 g/mol. As a result, the nanostructure repeat unit size was reduced to 30.2 nm.

Finally, the SEM images of FIGS. 4a and 4b demonstrate the difference between thick and thin films. The film in FIG. 4a is a multilayer structure on silicon, while the film in FIG. 4b shows a single layer assembly. This is particularly exciting since it suggests that through appropriate parameter optimization, the thickness can be tailored without losing the structure control.

Further improvements in process control can be achieved by better understanding how different parameters control the overall quality of the films. In this manner, one can control the defect density of the films thus increasing the long-range order and can create macroscopically ordered thin films. The porosity of the multilayer films renders them promising model candidates for the understanding of low dielectric material properties as a function of film parameters like thickness, pore size and pore size distribution. The monolayer film allow access to the silicon substrate which could make it feasible to be used as an etch mask.

The subject hybrid organic-inorganic system offers another major advantage over the all-organic system: one can move through the phase space of the system simply by changing the amount of sol-gel precursor added. As noted before, an all-organic system has a fixed block fraction that is established at the time of polymerization and this determines the morphology of the resultant structures. Any desire to work with a different morphology would require the costly synthesis of a brand new polymer and time-consuming efforts for repeated process optimization. With the process of the subject invention, one can conveniently move to other morphologies (cylinders, cubic bicontinuous Plumber's Nightmare) within the same polymer very easily. This saves tremendously on the associated costs and time involved with using a new polymer.

The present sol-gel process is quite robust and can be used to incorporate various different transition metal alkoxides to the block copolymer. This would allow for both nanostructure and functionality control of the resultant thin film. For example, introduction of iron oxide or vanadium precursors could create magnetic or electrically conducting films, respectively. It is also possible that electric fields could be employed to direct the self-assembly and thereby control structure formation.

The potential use of such nanostructured silica films in applications is tremendous. For example, as already discussed, high etch resistivity as compared to all-organic films would allow use as lithographic masks or templates. Also, the robust nature of these films can withstand high temperature processing, opening the path for the production of components never before possible. Backfilling the pores with magnetic materials would lead to well-ordered magnetic islands, the leading candidate for ultra-high capacity information storage media. The feature sizes of these films are comparable with molecular features of biomolecules, e.g., the spacing of the two antigen binding sites of antibodies. One can thus anticipate their use as platforms for biological sensors. Finally, ordered porous structures of silica are interesting candidates for use as low dielectric material.

Although the invention has been disclosed in terms of a preferred embodiment and variations thereon, it will be understood that numerous additional variations and modifications could be made thereon without departing from the scope of the invention as defined in the following claims.

What is claimed is:

1. A method for forming nanostructures on silicon wafers comprising the steps of:
a) providing a silicon wafer;
b) providing a hybrid solution of organic and inorganic components;
c) coating said wafer with said solution of inorganic and organic components, thereby forming a structure of defined morphology on said wafer; and
d) heat treating said wafer to remove said organic components, whereby; an all-inorganic nanostructure remains on said wafer.

2. The method of claim 1, wherein said organic components comprise block copolymer components and said inorganic components comprise sol-gel precursors.

3. The method of claim 2, wherein said block copolymer components comprise poly (isoprene-block-ethylene oxide).

4. The method of claim 3, wherein said sol-gel precursors comprise 3-glycidoxy-propyltrimethoxysilane and aluminum-tri-sec-butoxide.

5. The method of claim 2, wherein said step of providing said hybrid solution comprises the steps of:
1) solvating a copolymer, thereby forming a copolymer solution;
2) forming a sol-gel precursor; and
3) mixing said so-gel precursor in said copolymer solution to form said hybrid solution.

6. The method of claim 5, wherein amounts of said sol-gel precursor and said copolymer that are contained in said hybrid solution are selected to be first amounts if a monolayer thin film nanostructure is desired to be formed on said wafer, and are selected to be second, higher amounts if a multilayer film nanostructure is desired to be formed on said wafer.

7. The method of claim 1, wherein said coating step comprises:
a) placing a wafer to be coated on a spin chuck;
b) flooding said wafer with said solution; and
c) spinning said wafer.

8. The method of claim 7, wherein said wafer is spun at a rotational speed of at least 2000 RPM.

9. The method of claim 1, further comprising the step of cleaning said wafer prior to said coating step.

10. The method of claim 9, wherein said wafer is cleaned first in at least one bath of water, ammonium hydroxide and hydrogen peroxide, and then with hydrofluoric acid.

11. The method of claim 1, wherein said heat treating step comprises baking said wafer in a vacuum oven and then calcining said wafer in a box furnace.

12. The method of claim 11, wherein said wafer is heated in said vacuum oven at 130 degrees C. for 1 hour.

13. The method of claim 12, wherein said box furnace is selected to have the following settings: set point temperature: 500° C.; ramp rate: 5° C./minute; and, soak time: 1 hour.
